(19) United States
(12) Patent Application Publication
(10) Pub. No.: US 2025/0233570 A1
(43) Pub. Date: Jul. 17, 2025

(54) RESONATOR CHIP AND MANUFACTURING METHOD THEREOF

(71) Applicant: TXC Corporation, Taipei City (TW)

(72) Inventors: Wen Yang Chung, Taipei City (TW); Jing-Kai Liao, Taipei City (TW); Jun-Xiang Zeng, Taipei City (TW); Yu Wen Feng, Taipei City (TW); Chi-Fei Su, Taipei City (TW); Tzu-Hsiu Peng, Taipei City (TW)

(73) Assignee: TXC Corporation, Taipei City (TW)

(21) Appl. No.: 18/617,610

(22) Filed: Mar. 26, 2024

(30) Foreign Application Priority Data
Jan. 17, 2024 (TW) 113101875

(51) Int. Cl. H03H 3/02; H03H 9/19; H10N 30/082

(52) U.S. Cl. CPC H03H 3/02; H03H 9/19; H10N 30/082

(57) ABSTRACT

A resonator chip and a manufacturing method thereof are provided. The manufacturing method of the resonator chip includes the following steps. A quartz wafer is provided. The quartz wafer has a first surface and a second surface opposite to the first surface. A first etching process is performed on the quartz wafer to form multiple inverted mesa portions, and the inverted mesa portions has a first thickness. The quartz wafer is singulated to form multiple resonator chips. Each of the resonator chips includes one of the inverted mesa portions. A second etching process is performed on the resonator chips to form chamfers at edges of the resonator chips.

### CROSS-REFERENCE TO RELATED APPLICATION

This application claims the priority benefit of Taiwan application serial no. 113101875, filed on Jan. 17, 2024. The entirety of the above-mentioned patent application is hereby incorporated by reference herein and made a part of this specification.

### BACKGROUND

### Technical Field

The disclosure relates to a chip and a manufacturing method thereof, and in particular to a resonator chip and a manufacturing method thereof.

### Description of Related Art

The quartz oscillator is an electronic element for generating oscillation frequencies. With the trend of electronic products becoming lighter, thinner, shorter, and smaller, the size of the quartz resonator is also shrinking. However, during the cutting process of the quartz resonator, cracks exceeding 5 μm may be easily generated at cutting edges, which causes the quartz resonator to be easily fragmented when impacted by an external force, thus affecting the reliability of the quartz resonator. Therefore, how to improve the reliability of the quartz oscillator is currently an issue that needs to be solved.

### SUMMARY

The disclosure provides a resonator chip and a manufacturing method thereof, which can reduce cracks at cutting edges, thereby improving reliability.

A manufacturing method of a resonator chip of the disclosure includes the following steps. A quartz wafer is provided. The quartz wafer has a first surface and a second surface opposite to the first surface. A first etching process is performed on the quartz wafer to form multiple inverted mesa portions. The inverted mesa portions have a first thickness. The quartz wafer is singulated to form multiple resonator chips. Each of the resonator chips includes one of the inverted mesa portions. A second etching process is performed on the resonator chips to form chamfers at edges of the resonator chips.

In an embodiment of the disclosure, the second etching process is an isotropic etching process.

In an embodiment of the disclosure, after performing the second etching process on the resonator chips, the inverted mesa portions have a third thickness, and the third thickness is less than the first thickness.

In an embodiment of the disclosure, a ratio of the third thickness to the first thickness is less than 0.9.

In an embodiment of the disclosure, performing the first etching process on the quartz wafer includes the following steps. A first recession is formed on the first surface of the quartz wafer. A second recession is formed on the second surface of the quartz wafer. The first recession corresponds to the second recession.

In an embodiment of the disclosure, the manufacturing method further includes the following steps. A mask layer is formed on the first surface and the second surface of the quartz wafer. The mask layer includes multiple openings, and positions of the openings define positions of the inverted mesa portions. The step of performing the first etching process on the quartz wafer includes immersing the quartz wafer in an etching solution to remove a part of the quartz wafer not covered by the mask layer.

In an embodiment of the disclosure, the step of forming the openings of the mask layer includes forming a patterned photoresist layer on the mask layer; removing the mask layer not covered by the patterned photoresist layer using the patterned photoresist layer as a mask to form the openings to expose the first surface and the second surface of a part of the quartz wafer; and removing the patterned photoresist layer.

In an embodiment of the disclosure, the step of singulating the quartz wafer includes defining a segmentation lane in the quartz wafer using a laser; and segmenting the quartz wafer into the resonator chips along the segmentation lane using wet etching.

The resonator chip of the disclosure includes an inverted mesa portion and a peripheral portion. The peripheral portion laterally surrounds the inverted mesa portion. A thickness of the inverted mesa portion is less than a thickness of the peripheral portion. There is at least one chamfer structure between a top surface or a bottom surface and an outer surface of the peripheral portion.

In an embodiment of the disclosure, an included angle between the at least one chamfer structure and the top surface or the bottom surface is between 95 degrees and 125 degrees.

In an embodiment of the disclosure, an edge of the peripheral portion has a notch.

In an embodiment of the disclosure, a depth of the notch is less than 4 μm.

In an embodiment of the disclosure, the at least one chamfer structure includes a first chamfer structure and a second chamfer structure, which are respectively located at the peripheral portion on two opposite sides of the inverted mesa portion. The first chamfer structure is an inclined surface connected between the bottom surface and the outer surface of the peripheral portion, and the second chamfer structure is an inclined surface connected between the top surface and the outer surface of the peripheral portion.

Based on the above, the resonator chip of the disclosure forms the inverted mesa portion through the two etching processes, which can modify the edge of the resonator chip while forming the inverted mesa portion with the predetermined thickness to reduce the occurrence of cracks, so as to reduce the possibility of fragmentation due to the resonator chip being impacted by an external force, thereby improving reliability.

### BRIEF DESCRIPTION OF THE DRAWINGS

FIG. 1A to FIG. 1L are schematic cross-sectional views of a manufacturing method of a resonator chip according to an embodiment of the disclosure.

FIG. 2 is a top view of the resonator chip of FIG. 1L.

FIG. 3 is a schematic cross-sectional view of a packaging structure according to an embodiment of the disclosure.

### DESCRIPTION OF THE EMBODIMENTS

Exemplary embodiments of the disclosure will be fully described below with reference to the drawings. However, the disclosure may be embodied in many different forms and should not be construed as limited to the embodiments set forth herein. In the drawings, sizes and thicknesses of various regions, parts, and layers are not drawn to actual scale for the sake of clarity.

Directional terms such as “upper”, “lower”, “front”, “back”, “left”, and “right” mentioned herein refer to the directions with reference to the drawings. Accordingly, the directional terms used are illustrative and not limiting of the disclosure.

In the following embodiments, the same or similar elements will adopt the same or similar numerals, and repeated descriptions will be omitted. In addition, features in different embodiments may be combined with each other without conflict, and simple equivalent changes and modifications made in accordance with the specification or the claims are still within the scope covered by the disclosure.

It will be understood that although terms such as “first”, “second”, and “third” may be used herein to describe various elements, components, regions, layers, and/or parts, the elements, components, regions, layers, and/or parts should not be limited by the terms. The terms are used to distinguish one element, component, region, layer, or part from another element, component, region, layer, or part. Therefore, a first element, component, region, layer, or part discussed below may be referred to as a second element, component, region, layer, or part without departing from the teachings herein.

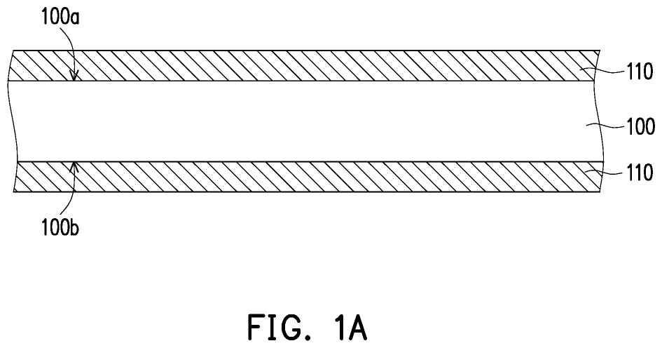

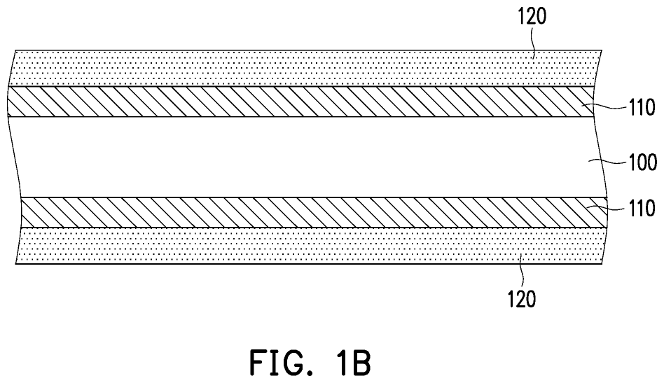

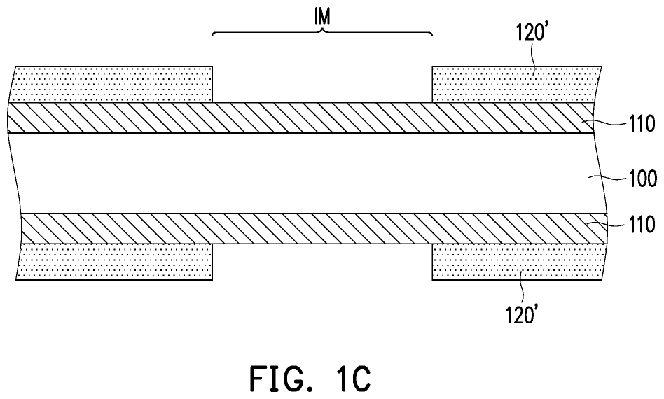

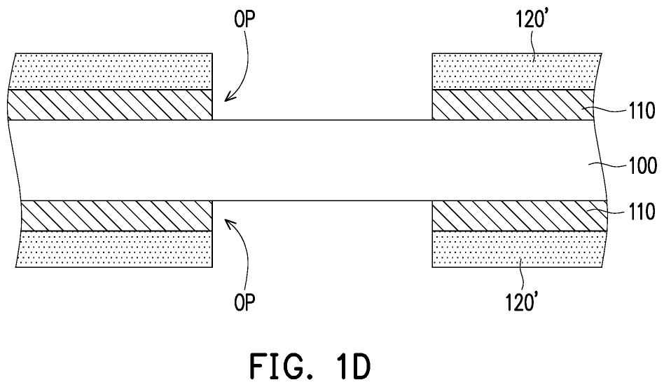

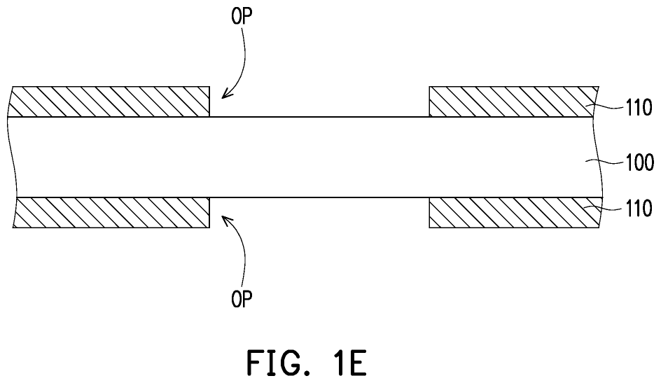

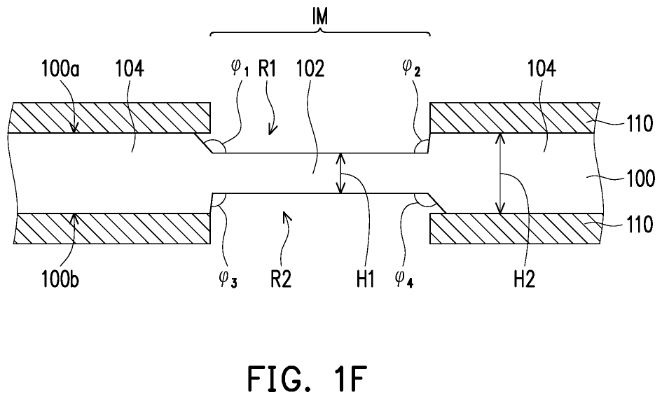

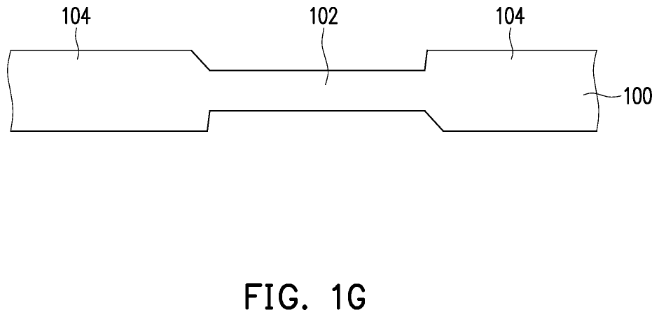

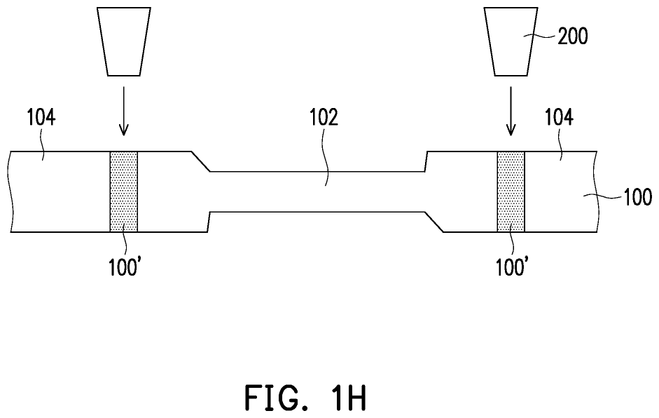

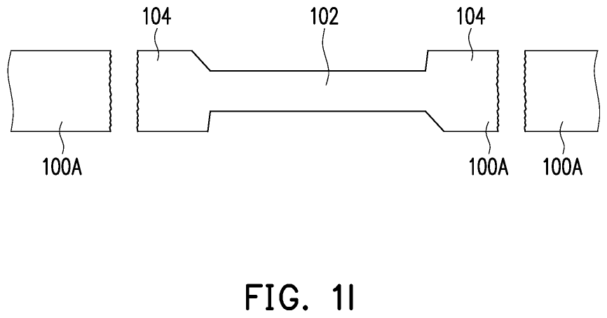

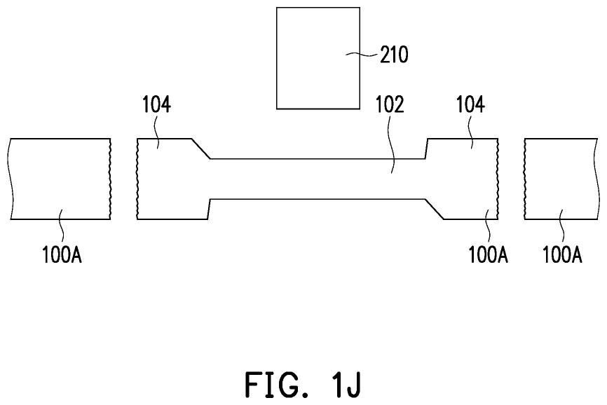

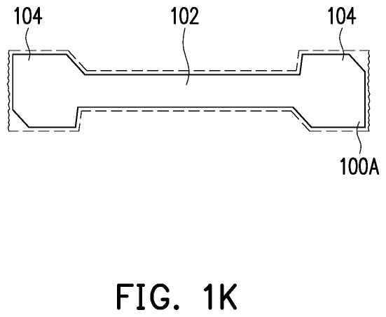

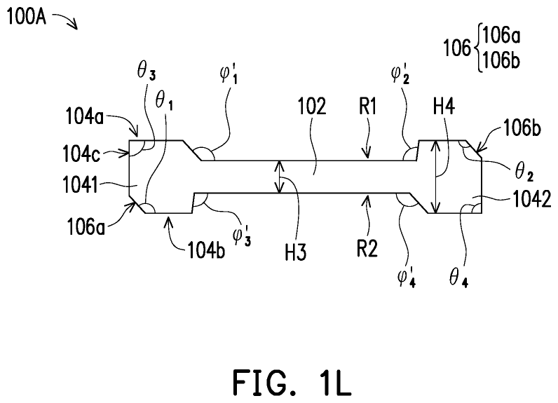

FIG. 1A to FIG. 1L are schematic cross-sectional views of a manufacturing method of a resonator chip according to an embodiment of the disclosure.

Please refer to FIG. 1A. A quartz wafer 100 is provided. The quartz wafer 100 has a first surface 100a and a second surface 100b opposite to the first surface 100a. In some embodiments, the quartz wafer 100 may be a single crystal structure.

Then, a mask layer 110 is formed on the first surface 100a and the second surface 100b of the quartz wafer 100. In some embodiments, the mask layer 110 includes a metallic material, such as gold, chromium, nickel, copper, or other suitable metallic materials. In some embodiments, the mask layer 110 may be formed using chemical vapor deposition, physical vapor deposition, or other suitable methods.

Please refer to FIG. 1B. A photoresist layer 120 is formed on the mask layer 110. In some embodiments, the photoresist layer 120 may be formed using spin coating, chemical vapor deposition, physical vapor deposition, or other suitable methods.

Please refer to FIG. 1C. The photoresist layer 120 is exposed and developed using a photomask (not shown) as a mask to form a patterned photoresist layer 120′. The patterned photoresist layer 120′ may define an inverted mesa region IM to be subsequently etched.

Please refer to FIG. 1D. The mask layer 110 not covered by the patterned photoresist layer 120′ is removed using the patterned photoresist layer 120′ as a mask to form multiple openings OP to expose the first surface 100a and the second surface 100b of a part of the quartz wafer 100. For example, wet etching may be used, in which a resulting structure is immersed in an etching solution with a high etching selectivity for the mask layer 110 to remove the mask layer 110 not covered by the patterned photoresist layer 120′. However, the disclosure is not limited thereto, and other suitable methods may also be used to remove the mask layer 110 not covered by the patterned photoresist layer 120′.

Please refer to FIG. 1E. The patterned photoresist layer 120′ is removed. In some embodiments, the patterned photoresist layer 120′ may be removed through an ashing process, a wet etching process, a dry etching process, a chemical mechanical polishing process, or other suitable methods.

Please refer to FIG. 1F. A first etching process is performed on the quartz wafer 100 using the mask layer 110 as a mask to form multiple inverted mesa portions 102. An unetched part of the quartz wafer 100 is also referred to as a peripheral portion 104. The inverted mesa portion 102 has a first thickness H1, the peripheral portion 104 has a second thickness H2, and the first thickness H1 is less than the second thickness H2. In some embodiments, a ratio of the first thickness H1 to the second thickness H2 is approximately between 0.45 and 0.65.

In some embodiments, the first etching process is a wet etching process. For example, the quartz wafer 100 may be immersed in the etching solution to selectively remove a part of the quartz wafer 100 not covered by the mask layer 110 to form a first recession R1 on the first surface 100a of the quartz wafer 100 in the inverted mesa region IM and form a second recession R2 on the second surface 100b of the quartz wafer 100. The first recession R1 corresponds to the second recession R2. In some embodiments, the depth of the first recession R1 is roughly the same as the depth of the second recession R2, but the disclosure is not limited thereto. In some embodiments, the etching solution used in the first etching process may be an etching solution with a high etching selectivity for the quartz wafer 100.

In some embodiments, the quartz wafer 100 has a faster etching rate in a lattice growth direction thereof, so that a part of the quartz wafer 100 located under the mask layer 110 is also etched. For example, in FIG. 1F, the left side of the first recession R1 extends under the mask layer 110, so that the left and right sides of the first recession R1 are asymmetrical to each other; and the right side of the second recession R2 extends under the mask layer 110, so that the left and right sides of the second recession R2 are asymmetrical to each other. In some embodiments, a bottom surface and side walls of the first recession R1 form an included angle φ1 and an included angle φ2, wherein the included angle φ1 and the included angle φ2 have different angles. For example, the angle of the included angle 1 is greater than the angle of the included angle φ2. In some embodiments, a bottom surface and side walls of the second recession R2 form an included angle φ3 and an included angle φ4, wherein the included angle φ3 and the included angle φ4 have different angles. For example, the angle of the included angle φ4 is greater than the angle of the included angle φ3.

After the quartz wafer 100 undergoes the first etching process, the inverted mesa portion 102 is initially formed. The inverted mesa portion 102 at this time does not have a predetermined thickness that the final resonator chip is intended to achieve. The first thickness H1 of the inverted mesa portion 102 may be between 1.1 times and 1.5 times the predetermined thickness of the resonator chip.

Please refer to FIG. 1G. The mask layer 110 is removed. In some embodiments, the mask layer 110 may be removed through a wet etching process, a dry etching process, a chemical mechanical polishing process, or other suitable methods.

Please refer to FIG. 1H and FIG. 1I. The quartz wafer 100 is singulated to form multiple resonator chips 100A, wherein each of the resonator chips 100A includes one of the inverted mesa portions 102. Specifically, in FIG. 1H, a segmentation lane 100′ is defined in the quartz wafer 100 using a laser 200. The quartz wafer 100 may be divided into the resonator chips 100A according to the segmentation lane 100′. A path scanned by the laser 200 on the quartz wafer 100 is the path of the segmentation lane 100′. Since the laser 200 has high energy, the laser-processed quartz wafer 100 (that is, the segmentation lane 100′) may be modified, for example, to have a twin crystal structure, so that the properties of the segmentation lane 100′ are different from those of the quartz wafer 100 without laser processing.

Afterwards, in FIG. 1I, wet etching is used to selectively etch the segmentation lane 100′, so that the quartz wafer 100 is segmented into the resonator chips 100A along the segmentation lanes 100′. Since the properties of the segmentation lane 100′ are different from those of the quartz wafer 100 without laser processing, the segmentation lane 100′ may be etched by selecting an etching solution with an appropriate etching selectivity to segment the quartz wafer 100 into the resonator chips. 100A. For example, the etching solution may include amine difluoride or other suitable etching solutions.

Please refer to FIG. 1J. A frequency measurement is performed on the inverted mesa portion 102 of the resonator chip 100A to calculate the time required for the subsequent etching process to achieve a predetermined frequency. For example, a space charge measurement system 210 may be used to perform the frequency measurement on the inverted mesa portion 102 of the resonator chip 100A, and the time required for the subsequent etching process to achieve the inverted mesa portion 102 with the predetermined thickness is then calculated according to a difference between the obtained frequency and the frequency value to be achieved.

Please refer to FIG. 1K and FIG. 1L. A second etching process is performed on the resonator chip 100A to etch the inverted mesa portion 102 to the predetermined thickness and form a chamfer structure 106 at an edge of the resonator chip 100A to modify the edge of the resonator chip 100A to reduce the occurrence of cracks. In FIG. 1K, for clarity of illustration, the profile of the resonator chip 100A before the second etching process is represented by a dotted line, and the profile of the resonator chip 100A after the second etching process is represented by a solid line.

In some embodiments, the second etching process is an isotropic etching process, such as a wet etching process. Therefore, each surface of the resonator chip 100A is etched to form the inverted mesa portion 102 with a third thickness H3 and the peripheral portion 104 with a fourth thickness H4, wherein the third thickness H3 is less than the first thickness H1, and the fourth thickness H4 is less than the second thickness H2. In some embodiments, a ratio of the third thickness H3 to the first thickness H1 is less than 0.9 or less than 0.88. In some embodiments, the ratio of the third thickness H3 to the first thickness H1 is between 0.8 and 0.9. In this way, the resonator chip 100A may be used to modify an edge through the second etching process and achieve the inverted mesa portion 102 with the predetermined thickness.

In some embodiments, since the resonator chip 100A has a faster etching rate in the lattice growth direction thereof, the chamfer structure 106 is easily formed at the edge of the resonator chip 100A in the lattice growth direction, and the first recession R1 and the second recession R2 are etched more in the lattice growth direction. For example, in FIG. 1L, the peripheral portion 104 includes a first part 1041 and a second part 1042, which are respectively located on opposite sides of the inverted mesa portion 102. The first recession R1 is etched more in a direction toward the first part 1041 (compared to a direction toward the second part 1042), and the second recession R2 is etched more in the direction toward the second part 1042 (compared to the direction toward the first part 1041), so that the left and right sides of the first recession R1 are asymmetrical to each other, and the left and right sides of the second recession R2 are asymmetrical to each other. On the other hand, the resonator chip 100A includes two chamfer structures (for example, a first chamfer structure 106a and a second chamfer structure 106b) respectively located between a bottom surface 104b and an outer surface 104c of the first part 1041 of the peripheral portion 104 and between a top surface 104a and the outer surface 104c of the second part 1042. In some embodiments, there is no chamfer structure between the top surface 104a and the outer surface 104c of the first part 1041 of the peripheral portion 104, and there is no chamfer structure between the bottom surface 104b and the outer surface 104c of the second part 1042 of the peripheral portion 104. In other words, the top surface 104a and the outer surface 104c of the first part 1041 of the peripheral portion 104 are basically perpendicular to each other, and the bottom surface 104b and the outer surface 104c of the second part 1042 of the peripheral portion 104 are basically perpendicular to each other. However, the disclosure is not limited thereto. In other embodiments, there may also be a chamfer structure between the top surface 104a and the outer surface 104c of the first part 1041 of the peripheral portion 104 and between the bottom surface 104b and the outer surface 104c of the second part 1042 of the peripheral portion 104.

Based on the above, the manufacturing of the resonator chip 100A of the embodiment may be roughly completed. Since the inverted mesa portion 102 of the resonator chip 100A is formed through two etching processes, the inverted mesa portion 102 is initially formed during the first etching process, and the inverted mesa portion 102 is then etched to the required thickness while modifying the edge of the resonator chip 100A during the second etching process, which can reduce the occurrence of cracks, thereby improving the reliability of the resonator chip 100A.

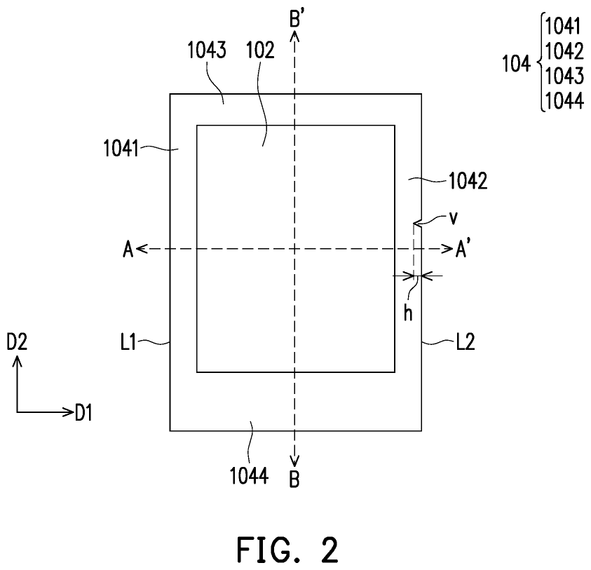

FIG. 2 is a top view of the resonator chip of FIG. 1L. FIG. 1L may be a cross-sectional view cut along a line A-A′ of FIG. 2. Specifically, FIG. 1L is a cross-sectional view cut along a short side direction D1 of the resonator wafer 100A.

Please refer to FIG. 1L and FIG. 2. The resonator chip 100A includes the inverted mesa portion 102 and the peripheral portion 104. The peripheral portion 104 laterally surrounds the inverted mesa portion 102, and the thickness (that is, the third thickness H3) of the inverted mesa portion 102 is less than the thickness (that is, the fourth thickness H4) of the peripheral portion 104. There is at least one chamfer structure 106 between the top surface 104a or the bottom surface 104b and the outer surface 104c of the peripheral portion 104.

In some embodiments, the thickness (that is, the third thickness H3) of the inverted mesa portion 102 is between 5 μm and 20 μm, but the disclosure is not limited thereto, and the thickness of the inverted mesa portion 102 may be adjusted according to actual requirements.

The peripheral portion 104 may include the first part 1041, the second part 1042, a third part 1043, and a fourth part 1044 respectively connected around the inverted mesa portion 102. The first part 1041 is opposite to the second part 1042, and the third part 1043 is opposite to the fourth part 1044. For example, in FIG. 2, the first part 1041 is located on the left side of the inverted mesa portion 102, the second part 1042 is located on the right side of the inverted mesa portion 102, the third part 1043 is located on the upper side of the inverted mesa portion 102, and the fourth part 1044 is located on the lower side of the inverted mesa portion 102. In some embodiments, the width of the fourth part 1044 is wider than the widths of the first part 1041, the second part 1042, and the third part 1043 to serve as a connecting portion with other components in a subsequent packaging structure. (The width of the first part 1041 refers to a distance between an edge of the first part 1041 and an edge of the inverted mesa portion 102 closest to the first part 1041 when viewed from a top view; the width of the second part 1042 refers to a distance between an edge of the second part 1042 and an edge of the inverted mesa portion 102 closest to the second part 1042 when viewed from a top view; the width of the third part 1043 refers to a distance between an edge of the third part 1043 and an edge of the inverted mesa portion 102 closest to the third part 1043 when viewed from a top view; and the width of the fourth part 1044 refers to a distance between an edge of the fourth part 1044 and an edge of the inverted mesa portion 102 closest to the fourth part 1044 when viewed from a top view.)

In some embodiments, the chamfer structure 106 is, for example, an inclined surface connected to the top surface 104a or the bottom surface 104b and the outer surface 104c of the peripheral portion 104. Specifically, in FIG. 1L, the resonator chip 100A includes two chamfer structures (for example, the first chamfer structure 106a and the second chamfer structure 106b) respectively located at (for example, the first part 1041 and the second part 1042 of) the peripheral portion 104 on two opposite sides of the inverted mesa portion 102. The first chamfer structure 106a is, for example, an inclined surface connected between the bottom surface 104b and the outer surface 104c of the first part 1041 of the peripheral portion 104, and there is an included angle θ₁ between the first chamfer structure 106a and the bottom surface 104b of the first part 1041. The second chamfer structure 106b is, for example, an inclined surface connected between the top surface 104a and the outer surface 104c of the second part 1042 of the peripheral portion 104, and there is an included angle θ₂ between the second chamfer structure 106b and the top surface 104a of the second part 1042. In some embodiments, the included angle θ₁ and the included angle θ₂ may be respectively between 95 degrees and 125 degrees. In this way, the possibility of cracks occurring at the edge of the resonator chip 100A can be reduced.

In some embodiments, there is an included angle θ₃ between the top surface 104a and the outer surface 104c of the first part 1041, and the included angle θ₁ is basically greater than the included angle θ₃; and there is an included angle θ₄ between the bottom surface 104b and the outer surface 104c of the second part 1042, and the included angle θ₂ is basically greater than the included angle θ₄.

In some embodiments, the top surface 104a and the outer surface 104c of the first part 1041 are basically vertically connected, and the bottom surface 104b and the outer surface 104c of the second part 1042 are basically vertically connected. In some embodiments, the included angle θ₃ and the included angle θ₄ may be respectively between 85 degrees and 115 degrees, but the disclosure is not limited thereto.

In some embodiments, after the above processes, as shown in FIG. 1L, the bottom surface and the side walls of the first recession R1 form an included angle φ₁′ and an included angle φ₂′ opposite to each other in the short side direction D1, wherein the angle of the included angle φ₁′ is greater than the angle of the included angle φ₂′, and the bottom surface and the side walls of the second recession R2 form an included angle φ₃′ and an included angle φ₄′ opposite to each other in the short side direction D1, wherein the angle of the included angle φ₄′ is greater than the angle of the included angle φ₃′. In some embodiments, the included angle φ₁′ and the included angle φ₄′ may be respectively between 140 degrees and 170 degrees, but the disclosure is not limited thereto. In some embodiments, the included angle φ₂′ and the included angle φ₃′ may be respectively between 92 degrees and 112 degrees, but the disclosure is not limited thereto. In some embodiments, the included angle φ₁′ and the included angle φ₃′ are respectively located on two sides of the inverted mesa portion 102 and are opposite to each other, and the included angle φ₂′ and the included angle φ₄′ are respectively located on two sides of the inverted mesa portion 102 and are opposite to each other.

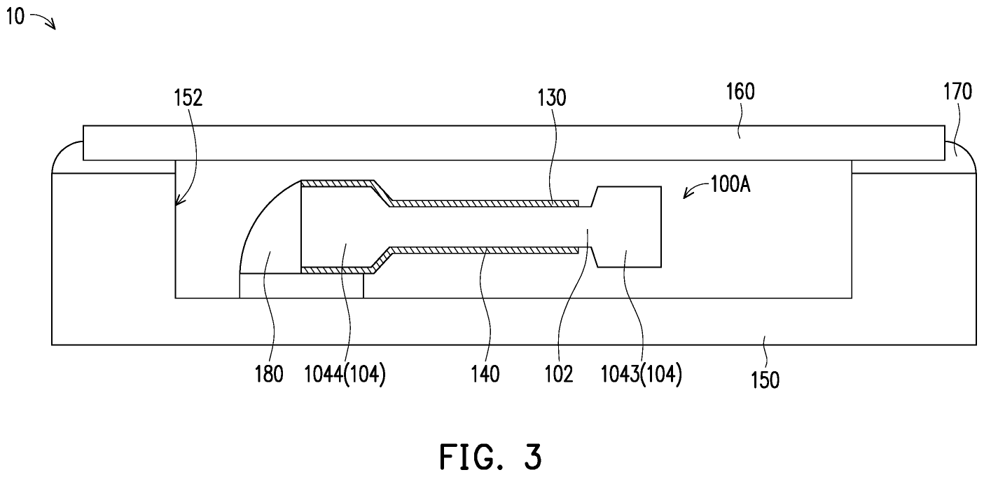

In some embodiments, the third part 1043 and the fourth part 1044 of the peripheral portion 104 basically do not have a chamfer structure (refer to the cross-sectional view shown in FIG. 3). In other words, the top surface 104a and the bottom surface 104b of the third part 1043 and the fourth part 1044 are basically respectively vertically connected to the outer surface 104c, but the disclosure is not limited thereto.

In some embodiments, as shown in FIG. 2, an edge L1 of the first part 1041 and/or an edge L2 of the second part 1042 of the peripheral portion 104 may have a notch v. In some embodiments, a depth h of the notch v is less than 4 μm. In this way, even if the resonator chip 100A is impacted by an external force, the external force may still be within a stress tolerance range thereof, thereby reducing the possibility of fragmentation. In the disclosure, the depth h of the notch v refers to a vertical distance between the tip of the notch v and the edge where the notch v is located. In FIG. 2, the notch v is only schematically shown at the edge L2 of the second part 1042, but the disclosure is not limited thereto. There may be one or more notches v respectively at the edge L1 of the first part 1041 and the edge L2 of the second part 1042.

FIG. 3 is a schematic cross-sectional view of a packaging structure according to an embodiment of the disclosure. It must be noted here that the embodiment of FIG. 3 continues to use the reference numerals and some content of the embodiment of FIG. 1L, wherein the same or similar numerals are adopted to represent the same or similar elements, and the description of the same technical content is omitted. For the description of the omitting part, reference may be made to the foregoing embodiment, which will not be described again here. FIG. 3 shows the resonator chip 100A and may be a cross-sectional view cut along a line B-B′ of FIG. 2, that is, FIG. 3 shows the resonator chip 100A and is a cross-sectional view cut along a long side direction D2 of the resonator chip 100A. (The long side direction D2 and the short side direction D1 are perpendicular to each other.)

Please refer to FIG. 3. A packaging structure 10 includes the resonator chip 100A, a first electrode 130, a second electrode 140, a base 150, and an upper cap 160. The resonator chip 100A may be the resonator chip 100A of FIG. 1L. For relevant content, reference may be made to the foregoing description, which will not be described again here. The first electrode 130 and the second electrode 140 may be respectively disposed on opposite surfaces of the inverted mesa portion 102 of the resonator chip 100A. For example, the first electrode 130 is located on the top surface of the inverted mesa portion 102, and the second electrode 140 is located on the bottom surface of the inverted mesa portion 102. A region of the inverted mesa portion 102 between the first electrode 130 and the second electrode 140 is a vibration region, and the thickness of the inverted mesa portion 102 may determine the oscillation frequency of the vibration region. In some embodiments, the first electrode 130 and the second electrode 140 may respectively extend to the peripheral portion 104 of the resonator chip 100A along the top surface and the bottom surface of the inverted mesa portion 102. In some embodiments, the resonator chip 100A, the first electrode 130, and the second electrode 140 may form a resonator or an oscillator.

The base 150 has an accommodating space 152, so that the resonator chip 100A may be disposed in the accommodating space 152. The upper cap 160 is disposed on the base 150 to cover the resonator chip 100A and close the accommodating space 152. In some embodiments, the packaging structure 10 may further include a seal ring or an adhesive layer 170 to seal the upper cap 160 and the base 150. In some embodiments, the resonator chip 100A may adhere the fourth part 1044 of the peripheral portion 104 of the resonator chip 100A to the base 150 through an adhesive 180, that is, the first part 1041, the second part 1042, and the third part 1043 of the peripheral portion 104 of the resonator chip 100A are basically suspended. The adhesive 180 is, for example, conductive glue to connect the first electrode 130 and the second electrode 140 to corresponding pads (not shown) or circuits (not shown) in the base 150.

The packaging structure 10 shows an application manner of the resonator chip 100A. Since cracks at the edge of the resonator chip 100A are reduced, the possibility of fragmentation due to the resonator chip 100A being impacted by an external force can be reduced, thereby improving the reliability of the packaging structure 10.

In summary, the resonator chip of the disclosure forms the inverted mesa portion through the two etching processes, which can modify the edge of the resonator chip while forming the inverted mesa portion with the predetermined thickness to reduce the occurrence of cracks, so as to reduce the possibility of fragmentation due to the resonator chip being impacted by an external force, thereby improving reliability.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A manufacturing method of a resonator chip, comprising:
providing a quartz wafer, wherein the quartz wafer has a first surface and a second surface opposite to the first surface;
performing a first etching process on the quartz wafer to form a plurality of inverted mesa portions, wherein the inverted mesa portions have a first thickness;
singulating the quartz wafer to form a plurality of resonator chips, wherein each of the resonator chips comprises one of the inverted mesa portions; and
performing a second etching process on the resonator chips to form chamfers at edges of the resonator chips.

2. The manufacturing method of the resonator chip according to claim 1, wherein the second etching process is an isotropic etching process.

3. The manufacturing method of the resonator chip according to claim 1, wherein after performing the second etching process on the resonator chips, the inverted mesa portions have a third thickness, and the third thickness is less than the first thickness.

4. The manufacturing method of the resonator chip according to claim 3, wherein a ratio of the third thickness to the first thickness is less than 0.9.

5. The manufacturing method of the resonator chip according to claim 1, wherein performing the first etching process on the quartz wafer comprises:
forming a first recession on the first surface of the quartz wafer; and
forming a second recession on the second surface of the quartz wafer, wherein the first recession corresponds to the second recession.

6. The manufacturing method of the resonator chip according to claim 1, further comprising:
forming a mask layer on the first surface and the second surface of the quartz wafer, wherein the mask layer comprises a plurality of openings, and positions of the openings define positions of the inverted mesa portions,
wherein the step of performing the first etching process on the quartz wafer comprises:
immersing the quartz wafer in an etching solution to remove a part of the quartz wafer not covered by the mask layer.

7. The manufacturing method of the resonator chip according to claim 6, wherein the step of forming the openings of the mask layer comprises:
forming a patterned photoresist layer on the mask layer;
removing the mask layer not covered by the patterned photoresist layer using the patterned photoresist layer as a mask to form the openings to expose the first surface and the second surface of a part of the quartz wafer; and
removing the patterned photoresist layer.

8. The manufacturing method of the resonator chip according to claim 1, wherein the step of singulating the quartz wafer comprises:
defining a segmentation lane in the quartz wafer using a laser; and
segmenting the quartz wafer into the resonator chips along the segmentation lane using wet etching.

9. A resonator chip, comprising:
an inverted mesa portion; and
a peripheral portion, laterally surrounding the inverted mesa portion, wherein a thickness of the inverted mesa portion is less than a thickness of the peripheral portion,
wherein there is at least one chamfer structure between a top surface or a bottom surface and an outer surface of the peripheral portion.

10. The resonator chip according to claim 9, wherein an included angle between the at least one chamfer structure and the top surface or the bottom surface is between 95 degrees and 125 degrees.

11. The resonator chip according to claim 9, wherein an edge of the peripheral portion has a notch.

12. The resonator chip according to claim 11, wherein a depth of the notch is less than 4 μm.

13. The resonator chip according to claim 9, wherein the at least one chamfer structure comprises:
a first chamfer structure and a second chamfer structure, respectively located at the peripheral portion on two opposite sides of the inverted mesa portion, wherein the first chamfer structure is an inclined surface connected between the bottom surface and the outer surface of the peripheral portion, and the second chamfer structure is an inclined surface connected between the top surface and the outer surface of the peripheral portion.
